(19) United States
(12) Patent Application Publication
(10) Pub. No.: US 2026/0324327 A1
(43) Pub. Date: Oct. 15, 2026

(54) PLASMA PROCESSING METHOD

(71) Applicant: Hitachi High-Tech Corporation, Minato-ku, Tokyo (JP)

(72) Inventors: Naohiro YAMAMOTO, Tokyo (JP); Kenichi KUWAHARA, Tokyo (JP)

(21) Appl. No.: 19/099,595

(22) PCT Filed: Nov. 16, 2023
(86) PCT No.: PCT/JP2023/041320

§ 371 Date: Jan. 29, 2025

(51) Int. Cl. H10P 50/28; H10P 76/20

(52) U.S. Cl. CPC H10P 50/287; H10P 76/204

(57) ABSTRACT

The present disclosure provides a plasma processing method related to a technique for preventing a skirt shape seen in a lower layer portion of an organic film. The plasma processing method for forming a mask by etching an organic film using plasma includes: a first step of etching an inorganic film formed on the organic film; a second step of etching the organic film using a sulfur-containing gas after the first step; a third step of removing a deposited film deposited on an etching target film formed below the organic film after the second step; and a fourth step of etching the organic film after the third step.

### DESCRIPTION

### Technical Field

The present disclosure relates to a plasma processing method, and is applicable to a plasma processing method related to a vertical processing technique for vertically processing an organic film used for fine pattern processing.

### Background Art

With a progress of high resolution lithography, extreme ultraviolet lithography using extreme ultraviolet (EUV) is developed as a finer processing technique, and development of a fine processing technique for a Tri-Layer (three-layer) organic film pattern using an EUV pattern is progressing. Among them, there is a demand for development of a technique for processing an organic film (ACL: amorphous carbon) applied to a mandrel of a self-aligned double patterning (SADP) with high accuracy. In particular, a processed shape of the organic film needs to be verticalized, and there is a demand for a technique for controlling a difference between a Top-CD value and a Bottom-CD value of the organic film to a minimum. In terms of processing accuracy, vertical processing with a Line-CD value of 16 nm or less is required. Here, CD is an abbreviation for critical dimension.

In the related art (JP2021-77843A), a method of preventing side etching of an upper portion of an organic film is proposed. However, it is considered that a processing method for the lower portion of the organic film is not studied.

### CITATION LIST

### Patent Literature

PTL 1: JP2021-77843A

### SUMMARY OF INVENTION

### Technical Problem

A high-precision processing technique of fine processing with a pattern dimension of 16 nm or less using an EUV pattern is required, and an etching process of vertically processing an organic film, which is a lower layer film of a Tri-Layer structure sample, is important. When the processed shape of the organic film has a tapered shape or a skirt shape seen in the lower layer portion of the organic film, dimensional controllability of the pattern is deteriorated, and a device performance and reliability of a semi-conductive product are deteriorated.

The present disclosure provides a plasma processing method related to a technique for preventing a skirt shape seen in a lower layer portion of an organic film.

### Solution to Problem

According to one embodiment of the present disclosure, a plasma processing method for forming a mask by etching an organic film using plasma includes:
a first step of etching an inorganic film formed on the organic film;
a second step of etching the organic film using a sulfur-containing gas after the first step;
a third step of removing a deposited film deposited on an etching target film formed below the organic film after the second step; and
a fourth step of etching the organic film after the third step.

In the fourth step, the organic film is etched using an H-containing gas (hydrogen-containing gas) or a mixed gas of the H-containing gas and an Ar gas. Accordingly, a skirt shape portion of the lower portion of the organic film is processed.

The sulfur-containing gas is an SO₂ gas or a COS gas. The deposited film is an oxide-based deposited film, for example, a sulfur-oxide-based deposited film.

A pattern formed on the inorganic film may be a carbon-based pattern or an oxide-based pattern.

### Advantageous Effects of Invention

According to an embodiment of the present disclosure, by performing the third step of removing the deposited film (oxide deposition film) attached after the etching process (second step) of the organic film (amorphous carbon film (ACL)) or the coating type organic lower layer (SOC) using the sulfur-containing gas (SO₂ gas or COS gas), and the fourth step of etching the organic film from which the deposited film is removed, it is possible to establish the vertically processed shape of the organic film and to prevent a variation in the processed dimension of the organic film.

### BRIEF DESCRIPTION OF DRAWINGS

FIG. 1 is a schematic cross-sectional view of a plasma etching apparatus according to the present disclosure.

FIG. 2A is a flowchart showing a plasma etching method according to the present disclosure, and is a cross-sectional view showing a cross-sectional structure of a wafer to be subjected to plasma etching.

FIG. 2B is a flowchart showing the plasma etching method according to the present disclosure, and is a cross-sectional view showing a step of etching an inorganic film.

FIG. 2C is a flowchart showing the plasma etching method according to the present disclosure, and is a cross-sectional view showing a step of etching an organic film and a partially enlarged cross-sectional view thereof.

FIG. 2D is a flowchart showing the plasma etching method according to the present disclosure, and is a cross-sectional view showing a step of removing a deposited film deposited on an etching target film formed below the organic film and a partially enlarged cross-sectional view thereof.

FIG. 2E is a flowchart showing the plasma etching method according to the present disclosure, and is a cross-sectional view showing a step of etching a skirt shape portion of the organic film and a partially enlarged cross-sectional view thereof.

FIG. 3A is a diagram showing components of a deposition film attached after an organic film etching process.

FIG. 3B is a diagram showing components of the organic film when the deposition film is removed after the organic film etching process.

FIG. 4 is a diagram showing an etching flow according to a plasma processing method of the present disclosure.

FIG. 5 is a diagram showing an example of etching conditions in each step of the plasma processing method according to the present disclosure.

### DESCRIPTION OF EMBODIMENTS

Hereinafter, an embodiment of the present disclosure will be described with reference to the drawings. However, in the following description, the same components are denoted by the same reference signs, and repeated description thereof may be omitted. It should be noted that the drawings may be shown more schematically than actual aspects to make the description clearer, but are merely examples and do not limit interpretation of the invention. Examples

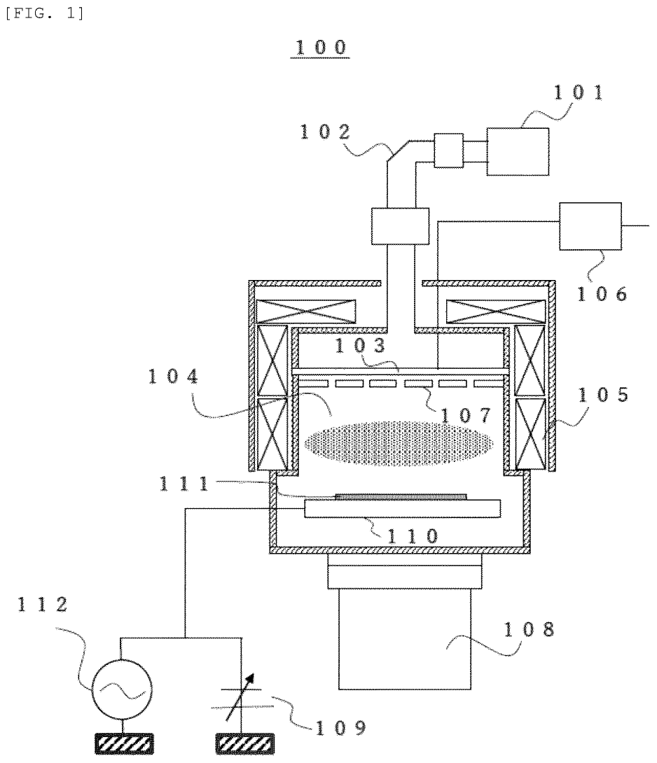

A plasma etching apparatus 100 as a plasma processing apparatus for implementing the present disclosure will be described with reference to FIG. 1. FIG. 1 is a schematic cross-sectional view of a microwave plasma etching apparatus of an electro cyclotron resonance (ECR) type using microwaves and a magnetic field as a plasma generating unit.

The microwaves are oscillated by a magnetron 101, pass through a waveguide tube 102, and propagate through a quartz plate 103 to a vacuum chamber 104. A solenoid coil 105 is provided around the vacuum chamber 104, and an electron cyclotron resonance (hereinafter, refer to as ECR) is generated by a magnetic field generated by the solenoid coil 105 and the microwaves propagated to the vacuum chamber 104.

An etching gas is supplied from a processing gas 106 and introduced into the vacuum chamber 104 via a shower plate 107. A pressure in the vacuum chamber 104 is adjusted to a desired pressure by evacuating an inside of the vacuum chamber 104 by a turbo molecular pump 108 and a dry pump (not shown) through an exhaust port (not shown) provided at the bottom of the vacuum chamber 104.

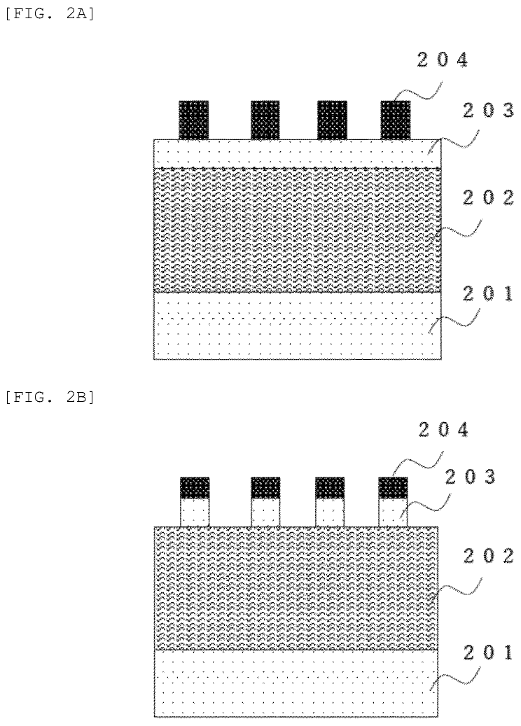

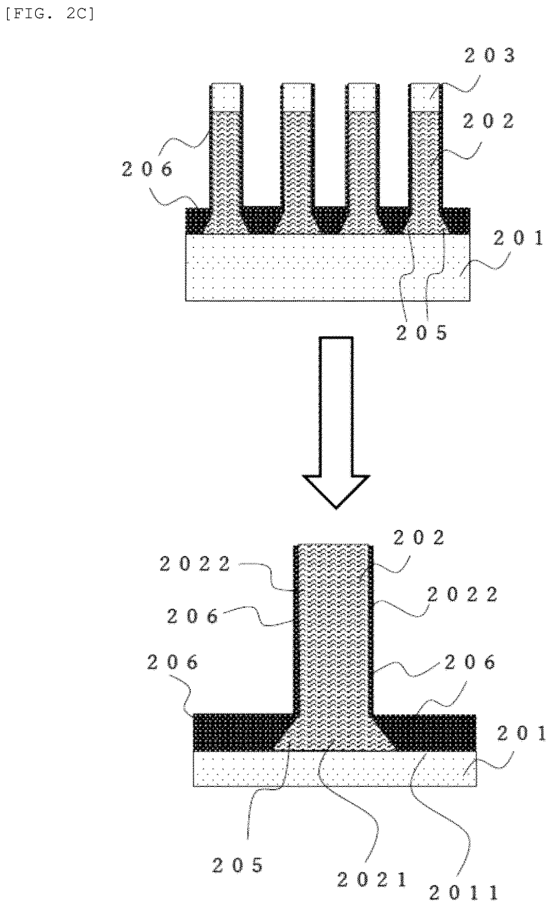

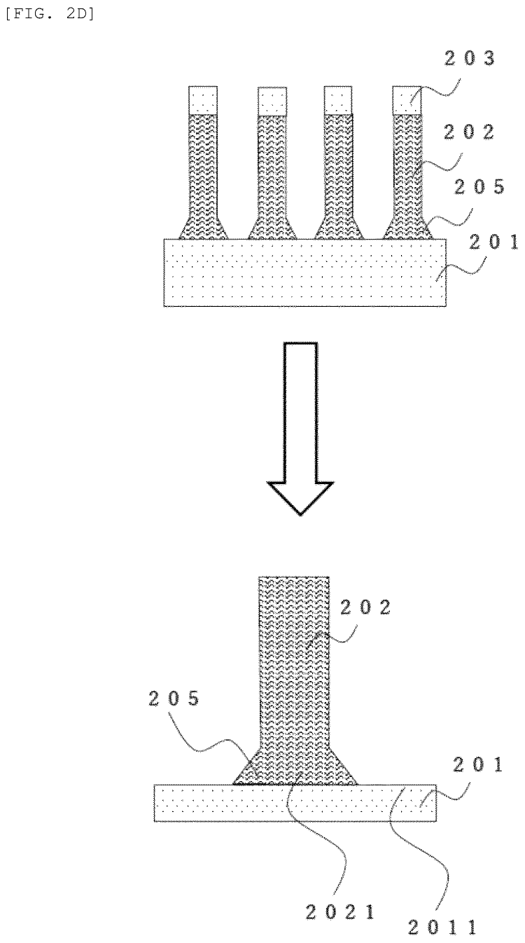

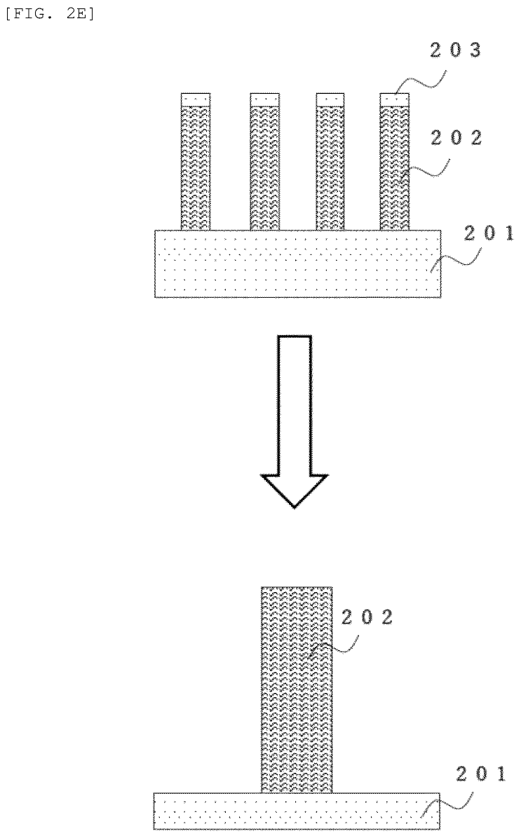

A wafer 111 is a sample on which an etching target film (inorganic film 201: see FIG. 2A) is formed, and is placed on a sample stage 110. A DC voltage is applied to the sample stage 110 by an electrostatic adsorption power source 109. Accordingly, the wafer 111 as the sample is attracted to the sample stage 110 by an electrostatic attraction force generated in the sample stage 110. In addition, a radio frequency power (hereinafter, referred to as a radio frequency (RF) bias) is supplied by a radio frequency power source 112 to the sample stage 110, and ions in plasma 5 are incident on the wafer 111 while being vertically accelerated.

Next, a plasma etching method as the plasma processing method according to the present disclosure will be described with reference to FIGS. 2A to 2E. FIG. 2A is a flowchart showing a plasma etching method according to the present disclosure, and is a cross-sectional view showing a cross-sectional structure of a wafer to be subjected to plasma etching. FIG. 2B is a flowchart showing the plasma etching method according to the present disclosure, and is a cross-sectional view showing a step of etching an inorganic film. FIG. 2C is a flowchart showing the plasma etching method according to the present disclosure, and is a cross-sectional view showing a step of etching an organic film and a partially enlarged cross-sectional view thereof. FIG. 2D is a flowchart showing the plasma etching method according to the present disclosure, and is a cross-sectional view showing a step of removing a deposited film deposited on an etching target film formed below the organic film and a partially enlarged cross-sectional view thereof. FIG. 2E is a flowchart showing the plasma etching method according to the present disclosure, and is a cross-sectional view showing a step of etching a skirt shape portion of the organic film and a partially enlarged cross-sectional view thereof.

First, a cross-sectional structure of the wafer 111 to be subjected to the plasma etching by the plasma processing method according to the present disclosure will be described.

As shown in FIG. 2A, in the wafer 111, the inorganic film 201 which is the etching target film, an organic film 202 having a thickness of 65 nm, an inorganic film 203 which is a spin-on-glass (SOG) film having a thickness of 10 nm, and a chemically amplified photoresist (CAR) 204 having a thickness of 22 nm which is patterned in advance by extreme ultraviolet (EUV) exposure are stacked on a silicon substrate (not shown) in this order from a bottom. The pattern which is patterned in advance in this embodiment is, for example, a groove pattern. The chemically amplified photoresist 204 is used as a mask, and may be referred to as the mask 204.

Dimensions patterned by the EUV exposure include not only dense patterns but also isolated patterns.

The organic film 202 is a carbon-based material such as an amorphous carbon (ACL) film or a coating type organic lower layer (SOC) film. Further, a material of the mask 204 patterned by the EUV exposure may be a metal oxide resist (MOR).

The wafer 111 shown in FIG. 2A is placed on the sample stage 110 of the plasma etching apparatus 100, and a plasma process to be described below is performed.

Next, a plasma etching method of the organic film 202 will be described.

First, the mask 204 patterned by the EUV exposure is initially used, and the inorganic film 203 is etched using a mixed gas of a sulfur hexafluoride (SF₆) gas and a fluoroform (CHF₃) gas or a mixed gas obtained by adding a hydrogen (H₂) gas to the mixed gas. When the mixed gas of the SF₆ gas and the CHF₃ gas is used, the inorganic film 203 is etched as shown in FIG. 2B under etching conditions in which a gas flow rate of the SF₆ gas is 15 mL/min, a gas flow rate of the CHF₃ gas is 100 mL/min, a processing pressure is 0.4 Pa, a microwave power is 1300 W, an RF bias is 50 W, and a processing time is 35 seconds (first step). That is, in the first step, the inorganic film 203 formed on the organic film 202 is etched using the mask 204 exposed to EUV.

A CD dimension can be controlled by over-etching the inorganic film 203 by 5% to 50% of the film thickness. Here, CD is an abbreviation of a critical dimension.

Next, the organic film 202 is etched using the inorganic film 203 etched in FIG. 2B as a mask. In the etching of the organic film 202, the organic film 202 is etched under etching conditions in which a sulfur-containing gas, for example, a mixed gas of a sulfur dioxide (SO₂) gas and an argon (Ar) gas is used, a gas flow rate of the SO₂ gas is 150 mL/min, a gas flow rate of the Ar gas is 500 mL/min, the processing pressure is 0.6 Pa, the microwave power is 900 W, the RF bias is 150 W, and the processing time is 100 sec. Accordingly, as shown in FIG. 2C, the organic film 202 is etched (second step). That is, after the first step, the organic film 202 is etched using the sulfur-containing gas in the second step.

In addition, as the sulfur-containing gas for etching the organic film 202, a mixed gas of a carbonyl sulfide (COS) gas, an oxygen (O₂) gas, and a nitrogen (N₂) gas may be used.

When a CD dimension of a processed shape obtained by performing an etching process on the organic film 202 is measured, it can be seen that a difference (CD difference) between an upper CD value (Top-CD value) of the organic film 202=9.72 nm and a lower CD value (Bottom-CD value) of the organic film=14.09 nm is 4.37 nm as a CD difference, which indicates that dimensional controllability is deteriorated. When the processed shape of the organic film 202 in which the CD difference occurs is observed in an SEM image, it can be seen that a skirt of the organic film 202 trails in a lower layer portion 2021 of the organic film 202. That is, the organic film 202 has a skirt shape portion 205 in the lower layer portion 2021.

In order to reduce the CD difference, the etching process conditions for the organic film 202 were used to remove the skirt shape portion 205 of the organic film 202, and over-etching of the organic film 202 was performed as additional etching. However, it was seen that the CD difference was 3.57 nm, and no significant improvement was observed.

In order to obtain detailed information on a shape of the organic film 202 after etching, the processed shape was observed using a TEM, and it was found that a deposition film 206 was deposited as shown in FIG. 2C. The deposition film 206 may be referred to as a deposited film.

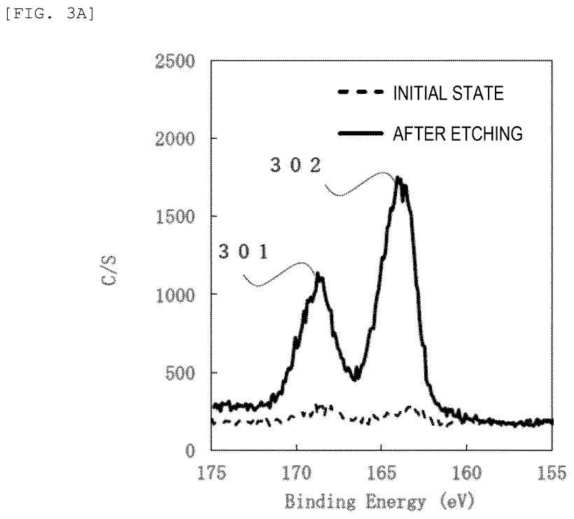

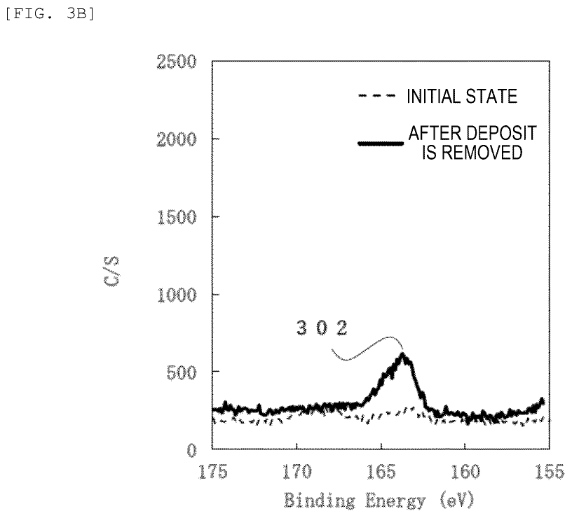

As a component analysis of the deposition film 206, an analysis is performed using an XPS analyzer, and as shown in FIG. 3A, it can be seen that sulfur oxide (SO₄²⁻) 301 and an organic sulfuric acid compound (S—C) 302 are deposited. As a result, since a carbon film is etched by the SO₂ gas during the etching of the organic film 202, the deposition film 206 is not formed, and the etching of the organic film 202 proceeds. However, when the organic film 202 is etched to a surface 2011 of the lower layer film 201 (inorganic film 201) and the organic film 202 is removed, the deposition film 206 is deposited on the surface 2011 of the lower layer film 201. In addition, since the deposition film 206 is also attached to a side wall 2022 of the organic film 202, side etching of the organic film 202 is prevented, and the organic film 202 can be processed into an anisotropic shape.

From this, it can be seen that since the deposition film 206 attaches to the organic film 202 and the lower layer film 201, the etching does not progress even when the over-etching is performed using the etching conditions of the organic film 202, and thus the skirt shape portion 205 of the organic film 202 cannot be removed and a vertical shape cannot be obtained. It is considered that, due to an influence of the above result, the CD difference increases and dimensional controllability deteriorates.

Next, a method for removing the deposition film 206 will be described. FIG. 3A is a diagram showing components of a deposition film attached after an organic film etching process. FIG. 3B is a diagram showing components of the organic film when the deposition film is removed after the organic film etching process.

The deposition film 206, which is a deposited film, is considered to be an oxide (oxide-based deposit) based on a measurement result (horizontal axis: binding (restraining) energy, vertical axis: count number) of the X-ray photoelectron spectroscopy (XPS) analyzer in FIG. 3A, and is subjected to the etching process using, for example, the etching conditions of the inorganic film 203. That is, the etching process is performed using the etching conditions of the inorganic film 203, in which the mixed gas of the SF₆ gas and the CHF₃ gas is used, the gas flow rate of the SF₆ gas is 15 mL/min, the gas flow rate of the CHF₃ gas is 100 mL/min, the processing pressure is 0.4 Pa, the microwave power is 1300 W, the RF bias is 0 W, and the processing time is 10 seconds. Here, in consideration of damage to the inorganic film 203 serving as the mask of the organic film 202, the deposition film 206 is removed using the etching condition in which the RF bias is set to 0 W, that is, the RF bias is not applied (third step). That is, after the second step, the deposited film 206 deposited on the etching target film 201 formed below the organic film 202 is removed in the third step. The third step S3 is performed by placing the sample 111 on which the etching target film 201 is formed on the sample stage 110 of the plasma etching apparatus 100 and setting the radio frequency power supplied to the sample stage 110 to 0 W.

As shown in FIG. 2D, it was confirmed by TEM observation that the deposition film 206 was removable. In addition, in the measurement result (horizontal axis: binding (restraining) energy, vertical axis: count number) of the X-ray photoelectron spectroscopy (XPS) analyzer in FIG. 3B, it can be seen that the sulfur oxide (SO₄²⁻) 301 returns to an initial state, and thus the deposition film 206 can be removed.

Next, the etching (fourth step) of the skirt shape portion 205 of the organic film 202 will be described. That is, in the fourth step, the organic film 202 after the third step is etched. In the fourth step, specifically, the skirt shape portion 205 of the organic film 202 is etched.

As described above, it can be seen that the deposition film 206 attached to the surface 2011 of the etching target film 201 and the side wall 2022 of the organic film 202 can be removed, the skirt shape portion 205 of the organic film 202 is etched, the processed shape of the organic film 202 is vertical, an etched shape of the organic film 202 shown in FIG. 2E is obtained, and the Top-CD value and the Bottom-CD value can be improved.

However, since the deposition film 206 attached to the side wall 2022 of the organic film 202 is also removed, when the conditions used in the etching of the organic film 202 are used, the side etching occurs in the side wall 2022, causing a problem of the CD value becoming thinner.

In consideration of such damage to the side wall 2022 of the organic film 202, it can be seen that it is necessary to examine process conditions mainly for sputtering etching by ions. The etching gas used in the sputtering etching is a mixed gas of the Ar gas as a rare gas and the hydrogen gas (H gas) as a hydrogen-containing gas (H-containing gas). In addition, the etching may be performed by using the H gas, such as, a hydrogen bromide (HBr) gas or a methane (CH₄) gas as the H-containing gas. For example, when the mixed gas of the Ar gas and the H₂ gas is used, the skirt shape portion 205 of the organic film 202 is etched under etching conditions in which a gas flow rate of the Ar gas is 100 mL/min, a gas flow rate of the H₂ gas is 100 mL/min, the processing pressure is 0.4 Pa, the microwave power is 900 W, the RF bias is 200 W, and the processing time is 20 seconds.

Further, since the Ar gas alone does not react with carbon, a C—H bond reaction is required, and the H-containing gas is required.

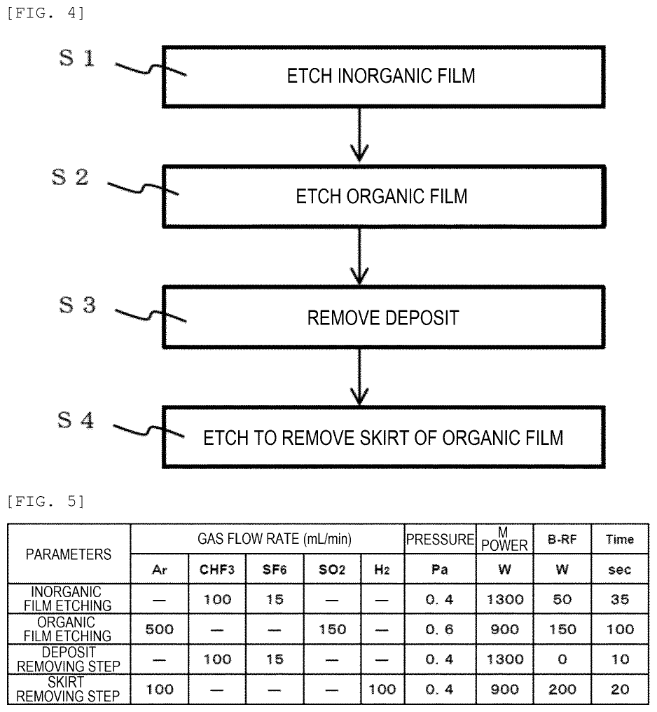

FIG. 4 is a diagram showing an etching flow according to a plasma processing method of the present disclosure. Further, FIG. 5 is a diagram showing an example of etching conditions set in each step of the plasma processing method according to the present disclosure. A vertical filed of FIG. 5 indicates the etching conditions of the inorganic film 203 in the first step S1, the etching conditions of the organic film 202 in the second step S2, the etching conditions of the deposited film 206 in the third step S3, and the etching conditions of the organic film 202 in the fourth step S4. A horizontal filed of FIG. 5 indicates, as parameters, a gas flow rate (mL/min) of a gas to be used, a processing pressure (unit: Pa) of the vacuum chamber 104, a value (unit: W) of the microwave power (M power), a value (unit: W) of the RF bias (B-RF), and a processing time(Time) (unit: sec).

The etching flow according to the plasma processing method of the present disclosure will be described with reference to FIGS. 4 and 5, and the description of FIGS. 2A to 2D and FIGS. 3A and 3B may be referred to for the detailed description.

The first step S1 is a step of etching the inorganic film 203 formed on the organic film 202. The etching conditions of the inorganic film 203 are described in “inorganic film etching” of FIG. 5. The inorganic film 203 is etched using the mask 204 exposed to EUV. The material of the mask 204 is, for example, the chemically amplified photoresist (CAR) or the metal oxide (MOR). The organic film 202 is, for example, the amorphous carbon layer (ACL) film or a film of the coating type organic lower layer (SOC) material.

The second step S2 is a step of etching the organic film 202 using the sulfur-containing gas after the first step S1. The etching conditions of the organic film 202 are described in “organic film etching” of FIG. 5. The sulfur-containing gas is, for example, the SO₂ gas or the COS gas.

The third step S3 is a step of removing the deposited film 206 deposited on the etching target film 201 formed below the organic film 202 after the second step S2. The etching conditions for removing the deposited film 206 are described in “deposit removing step”. The deposited film 206 is an oxide-based deposited film. The third step S3 is performed by setting the radio frequency power supplied to the sample stage 110 on which the sample 111 having the etching target film 201 formed thereon is placed to 0 W.

The fourth step S4 is a step of etching the organic film 202 (specifically, the skirt shape portion 205 of the organic film 202) after the third step S3. The etching conditions of the skirt shape portion 205 of the organic film 202 are described in “skirt removing step”. In the fourth step S4, the organic film 202 after the third step S3 is etched using the hydrogen-containing gas. The hydrogen-containing gas is, for example, the hydrogen gas.

Although the present disclosure has been specifically described above based on the embodiment, it is needless to say that the present disclosure is not limited to the above-described embodiment and can be variously changed.

### REFERENCE SIGNS LIST

100: plasma etching apparatus
101: magnetron
102: waveguide tube
103: quartz plate
104: vacuum chamber
105: solenoid coil
106: etching gas
107: shower plate
108: turbo molecular pump
109: electrostatic adsorption power source
110: sample stage
111: wafer (sample)
112: radio frequency power source
201: etching target material
202: organic film
203: inorganic film
204: resist
205: organic film skirt shape portion
206: deposition film
301: sulfur oxide (SO₄²⁻)
302: organic sulfuric acid compound (S—C)

1. A plasma processing method for forming a mask by etching an organic film using plasma, the plasma processing method comprising:
a first step of etching an inorganic film formed on the organic film;
a second step of etching the organic film using a sulfur-containing gas after the first step;
a third step of removing a deposited film deposited on an etching target film formed below the organic film after the second step; and
a fourth step of etching the organic film after the third step.

2. The plasma processing method according to claim 1, wherein
in the fourth step, the organic film after the third step is etched using a hydrogen-containing gas.

3. The plasma processing method according to claim 1, wherein
the deposited film is an oxide-based deposited film.

4. The plasma processing method according to claim 1, wherein
the sulfur-containing gas is an SO₂ gas or a COS gas.

5. The plasma processing method according to claim 1, wherein
the inorganic film is etched using a mask exposed to EUV.

6. The plasma processing method according to claim 5, wherein
a material of the mask is a chemically amplified photoresist (CAR) or a metal oxide (MOR).

7. The plasma processing method according to claim 1, wherein
the organic film is an amorphous carbon layer (ACL) film or a film of a coating type organic lower layer (SOC) material.

8. The plasma processing method according to claim 6, wherein
the organic film is an amorphous carbon layer (ACL) film or a film of a coating type organic lower layer (SOC) material.

9. The plasma processing method according to claim 1, wherein
the third step is performed by setting a radio frequency power supplied to a sample stage on which a sample formed with the etching target film is placed to 0 W.

10. The plasma processing method according to claim 8, wherein
in the fourth step, the organic film after the third step is etched using a hydrogen-containing gas.

11. The plasma processing method according to claim 10, wherein
the sulfur-containing gas is an SO₂ gas or a COS gas.

12. The plasma processing method according to claim 11, wherein
the hydrogen-containing gas is a hydrogen gas.
